(19) United States
(12) Patent Application Publication
(10) Pub. No.: US 2012/0091595 A1
(43) Pub. Date: Apr. 19, 2012

(54) Layered Integrated Circuit Apparatus

(75) Inventors: Sung Chuan MA, Taoyuan County (TW); Jimmy Liang, Zhongli City (TW)

(73) Assignee: MAO BANG ELECTRONIC CO., LTD., Taoyuan County (TW)

(21) Appl. No.: 12/906,791

(22) Filed: Oct. 18, 2010

(51) Int. Cl. H01L 23/52

(52) U.S. Cl. 257/777; 257/E23.141

(57) ABSTRACT

A device having layered integrated circuit (IC) chips is provided. The chip comprises notches, conductive area, apertures, and routing pool. A conductive material is set in the apertures. The second chip is layered on the first chip. The notches of the second chip are corresponding to the first conducting area of the first chip. A conductive material is also set in the notch between the conductive area of the first chip and the notches of the second chip. Thus, a system is integrated by layering the first chip and the second chip for enhancing flexibility and reliability of circuit layout.

### TECHNICAL FIELD OF THE DISCLOSURE

The present disclosure relates to integrated circuit (IC); more particularly, relates to filling notches or apertures with a conductive material on layering a first chip and a second chip by using circuit contacts and the notches or apertures to connect IC chips together with wires for achieving flexibility of circuit layout, easy fabrication and enhanced reliability.

### DESCRIPTION OF THE RELATED ARTS

A conventional IC integrating technique, as shown in FIG. 8, usually connects a fourth chip 400 and a fifth chip 500 through conductive wires 60 crossing along edges of the fourth chip 400 and the fifth chip 500 with junctures 40 on the fourth chip 400 and the fifth chip 500 after layering the fourth chip 400 and the fifth chip 500 for integrating the two chips according to a design of a circuit layout.

Even through the above conventional technique can communicate the fourth and the fifth chips 400,500 by conductive wires 60; however, it can only layer chips of the same size through a crossing connect method along edges of the fourth and the fifth chips 400,500. It limited system design and makes integration difficult because of lacking of flexibility. Moreover, it's hard to detect error owing to complex produce procedure, so that it increases product rejection rate.

Although the above prior art can be electrically connected with outside circuit with ease, its connection with the outside circuit is only on one surface. On piling up the chips, a plurality of apertures is required and a conductive material has to be filled into the apertures for connecting two surfaces. Therein, a tool is used to drill out the apertures on the chips; then, an insulative layer is formed on each wall of the apertures through printing, coating, jet printing, chemical vapor deposition (CVD), physical vapor deposition (PVD), sputtering, electroplating or electroless plating, so as to prevent the chips from short cut; and, then, the conductive material is filled into the apertures to connect two surfaces of the chips.

However, because the insulative layer has to be formed after the drilling and the conductive material has to be filled in, the fabrication becomes complicated with low yield and bad reliability. Hence, the prior art does not fulfill all users' requests on actual use.

### SUMMARY OF THE DISCLOSURE

The main purpose of the present disclosure is to filling notches or apertures with a conductive material on layering at least two chips with circuit contacts and the notches or apertures to connect IC chips for achieving flexibility of circuit layout, easy fabrication and improved reliability.

To achieve the above purpose, the present disclosure is a layered integrated circuit apparatus, comprising a first chip and a second chip, where the first chip has a plurality of first notches at edge; a first conductive area on a surface; a plurality of first apertures on the surface; and a first routing area on the surface to connect the notch or the aperture to the first conductive area; where a conductive material is formed in each of the first apertures; where the second chip is layered on the first chip; where the second chip has a plurality of second notches at edge corresponding to the first conductive area; a second conductive area on a surface; a plurality of second apertures on the surface; and a second routing area on the surface to connect the second notch or the second aperture to the second conductive area; where a conductive material is formed between the first conductive area and each of the second notches; where a conductive material is formed in each of the second apertures; and where the first apertures and the second apertures are formed through hot drilling with a first insulative layer and a second insulative layer formed on an inner surface of each of the first apertures and on an inner surface of each of the second apertures, respectively. Accordingly, a novel layered integrated circuit apparatus is obtained.

### BRIEF DESCRIPTIONS OF THE DRAWINGS

The present disclosure will be better understood from the following detailed descriptions of the preferred embodiments according to the present disclosure, taken in conjunction with the accompanying drawings, in which

FIG. 1 is the perspective view showing the first preferred embodiment according to the present disclosure;

FIG. 2 is the explosive view showing the first preferred embodiment;

FIG. 3 is the sectional view showing the first preferred embodiment;

FIG. 4 is the perspective view showing the second preferred embodiment;

FIG. 5 is the sectional view showing the second preferred embodiment;

FIG. 6 is the perspective view showing the third preferred embodiment;

FIG. 7 is the sectional view showing the forth preferred embodiment; and

FIG. 8 is the perspective view of the prior art.

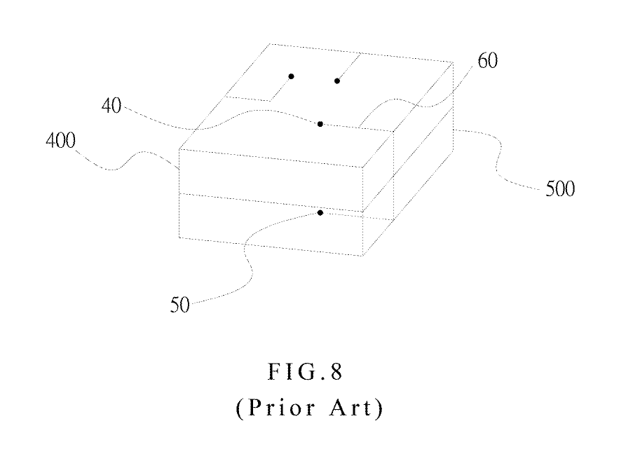

### DESCRIPTION OF THE PREFERRED EMBODIMENTS

The following descriptions of the preferred embodiments are provided to understand the features and the structures of the present disclosure.

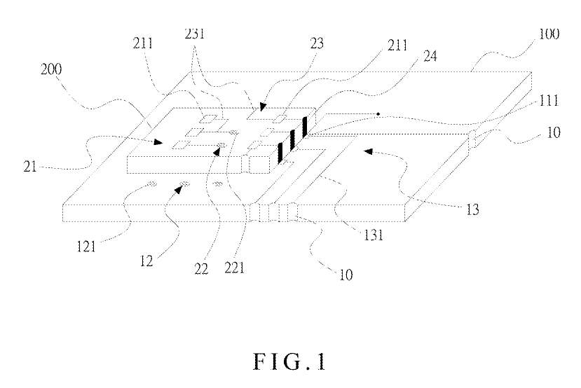

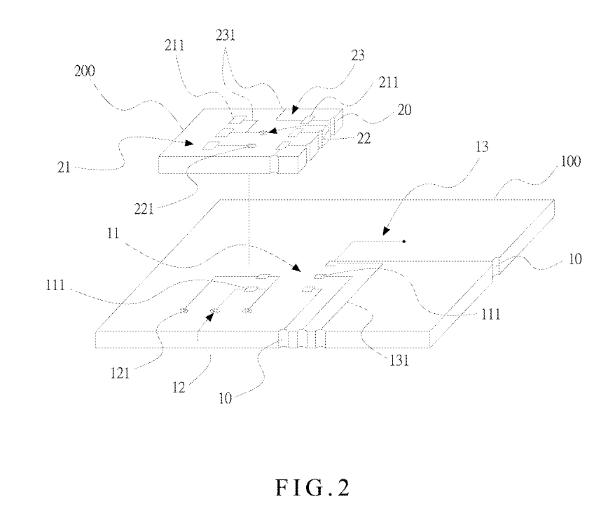

Please refer to FIG. 1 to FIG. 3, which are a perspective view, an explosive view and a sectional view showing a first preferred embodiment according to the present disclosure. As shown in the figures, the present disclosure is a layered integrated circuit apparatus, comprising at least a first chip 100 and a second chip 200. To integrate a system on the first chip 100 and the second chip 200, the first chip 100 and the second chip 200 are layered for achieving flexibility of circuit layout, easy fabrication and enhanced reliability and stability.

The first chip 100 comprises a substrate 101; a circuit layer 102 on the substrate 101; an insulative layer 103 on the circuit layer 102; and a circuit layer 104 on the insulation layer 103. A plurality of first notches 10 is set at edge of the first chip 100. The first chip 100 has a first conductive area 11; a plurality of first apertures 12; and a first routing pool 13 connecting the first notch 10 or the first aperture 12 to the first conductive area 11. Therein, a conductive material 14, such as a conductive silver paste, is set in the first aperture 12. A plurality of first circuit contacts 111 is set in the first conductive area 11; and, a plurality of first conductive wires 131 is set in the first routing pool 13. The first conductive wires 131 not only connect the first notches 10 and/or the first apertures 12 to the first conductive area 11; but also are extended to the other side of the first chip 100.

The second chip 200 is layered on a side of the first chip 100. The second chip 200 comprises a substrate 201; a circuit layer 202 on the substrate 201; an insulative layer 203 on the circuit layer 202; and a circuit layer 204 on the insulative layer 203. A plurality of second notches 20 are set at edge of the second chip 200 and are corresponding to the first conductive area 11. A conductive material 24 is set between the second notches 20 and the first conductive area 11. The conductive material 24 can be a conductive silver paste. The second chip 200 has a second conductive area 21; a plurality of second apertures 22; and a second routing pool 23 connecting the second notch 20 or the second aperture 22 to the second conductive area 21. The conductive material 24 is set in the second apertures 22. A plurality of second circuit contacts 211 is set in the second conductive area 21; and a plurality of second conductive wires 231 is set in the routing area 23. The second conductive wire 231 not only connects the second notch 20 or the second aperture 22 to the second conductive area 21; but also can be extended to the other side of the second chip 200.

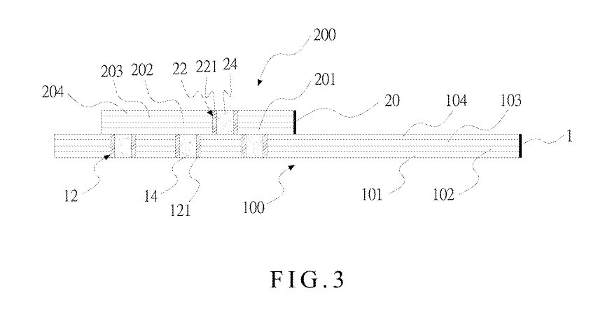

The first and the second chips 100,200 are made of silicon; doped silicon (e.g. boron-doped silicon); phosphorus; arsenic; or antimony, for forming an n-type or p-type material. The first aperture 12 in the first chip 100 and the second aperture 22 in the second chip 200 are formed in an oxygen environment by using a hot-drilling device, like a laser device. As shown in FIG. 3, a first insulative layer 121 and a second insulative layer 221 are also formed on inner surfaces of the first and the second apertures 12,22 when the first and the second apertures 12,22 are formed. Thus, a novel layered integrated circuit apparatus is obtained.

On using the present disclosure, the second notches 20 are set around the edge of the second chip 200 and the second apertures 22 are corresponding to the first conductive area 11. With the conductive material 24 between the first conductive area 11 and the second notches 20 and that in the second apertures 22, the first and the second chips 100,200 together with the first and the second conductive wires 231 are electrically connected with each other through the second notches 20 and the second apertures 22 for conducting two faces of the first and the second chips 100,200.

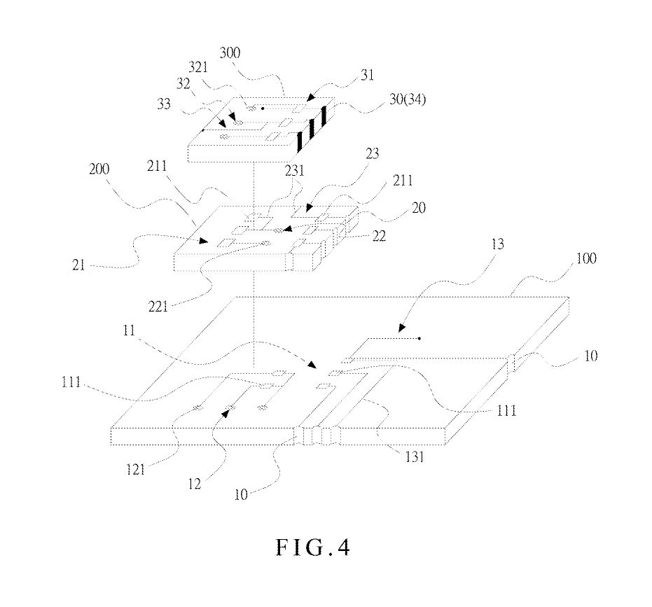

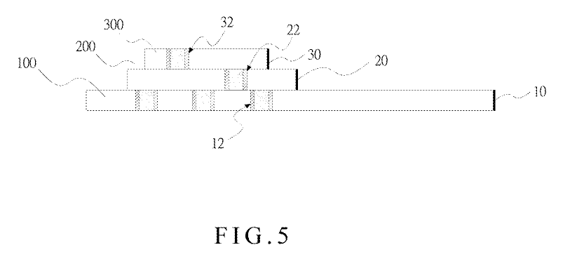

Please further refer to FIG. 4 and FIG. 5, which are a perspective view and a sectional view showing a second preferred embodiment. As shown in the figures, on using the present disclosure, a third chip 300 is layered on the second chip 200. A plurality of third notches 30 corresponding to the second conductive area 21 is set around edge of the third chip 300. A conductive material 34 is set between the second conductive area 21 and the third notches 30. The third chip 300 comprises a third conductive area 31; a plurality of third apertures 32; and a routing pool 33 connecting the third notch 30 or the third aperture 32 to the third conductive area 31. An insulative layer 321 is formed on inner surface of each of the third apertures 32; and the conductive material 34 is set in each of the third apertures 32. Thus, actual use of the present disclosure is enhanced by further layering the third chip 300 on the second chip 200.

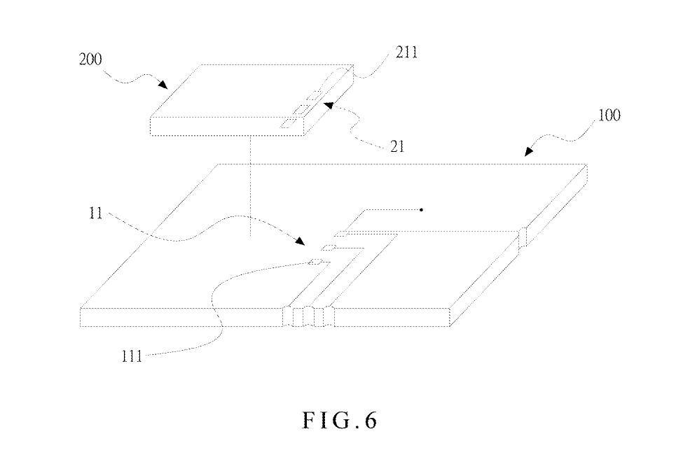

Please further refer to FIG. 6, which is a perspective view of a third preferred embodiment. As shown in the figure, on using the present disclosure, the second conductive area on the second chip 200 is directly correspondingly connected with the first conductive area 11 on the first chip 100 to layer the first and the second chips 100,200 for integrating system. Moreover, notches, apertures, conductive materials and routing pool on the second chip 200 are elective depending on actual use.

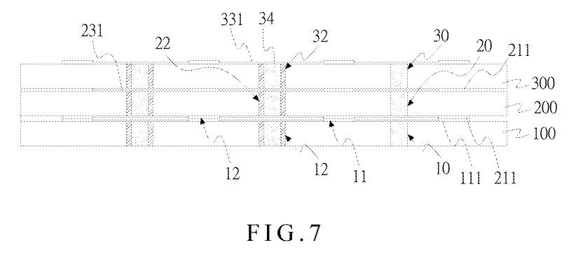

Please further refer to FIG. 7, which is a sectional view of a forth preferred embodiment. As shown in the figure, the present disclosure is used for layering chips having the same size. The first chip 100 and the second chip 200 are layered according to the third preferred embodiment by contacting the first and the second circuit contacts 111,211 on the first and the second conductive areas 11 with each other. The second chip 200 and the third chip 300 are layered according to the first preferred embodiment. The third notches 30 are set around the edge of the third chip 300 and the third apertures 32 are corresponding to the second conductive area 21. With the conductive material 34 between the second conductive area 21 and the third notches 30 and that in the third apertures 32, the second and the third chips 200,300 together with the second and the third conductive wires 231,331 are electrically connected with each other through the third notches 30 and the third apertures 32 for conducting two faces of the second and the third chips 100,200.

To sum up, the present disclosure is an integrated circuit layering device, where a system is integrated on a first and a second chips layered together for easy fabrication and enhanced reliability and stability.

The preferred embodiments herein disclosed are not intended to unnecessarily limit the scope of the disclosure. Therefore, simple modifications or variations belonging to the equivalent of the scope of the claims and the instructions disclosed herein for a patent are all within the scope of the present disclosure.

What is claimed is:

1. A layered integrated circuit apparatus, comprising:
a first chip, said first chip having
a plurality of first notches at edge of said first chip;
a first conductive area on a surface of said first chip;
a plurality of first apertures on said surface of said first chip; and
a first routing area on said surface of said first chip to connect said notch or said aperture to said first conductive area,
wherein a conductive material is obtained in each of said first apertures; and
a second chip, said second chip being located above said first chip, said second chip having
a plurality of second notches corresponding to said first conductive area at edge of said second chip,
wherein a conductive material is obtained between said first conductive area and each of said second notches;
a second conductive area on a surface of said second chip;
a plurality of second apertures on said surface of said second chip; and
a second routing area on said surface of said second chip to connect said second notch or said second aperture to said second conductive area,
wherein a conductive material is obtained in each of said second apertures,
wherein said first apertures and said second apertures are obtained through hot drilling with a first insulative layer and a second insulative layer obtained on an inner surface of each of said first apertures and on an inner surface of each of said second apertures, respectively.

2. The device according to claim 1,
wherein said first chip and said second chip each further comprises:
a substrate;
a first circuit layer on said substrate;
an insulative layer on said first circuit layer; and
a second circuit layer on said insulative layer.

3. The device according to claim 1,
wherein said first conductive area and said second conductive area have a plurality of first contacts and a plurality of second contacts, respectively.

4. The device according to claim 1,
wherein said first routing pool and said second routing pool have a plurality of first conductive wires and a plurality of second conductive wires, respectively.

5. The device according to claim 1,
wherein said conductive material is a conductive silver paste.

6. The device according to claim 1,
wherein a third chip is further located above said second chip;
wherein said third chip has
a plurality of third notches corresponding to said second conductive area at edge of said second chip,
wherein a conductive material is obtained between said second conductive area and each of said third notches;
a third conductive area on a surface of said third chip;
a plurality of third apertures on said surface of said third chip; and
a third routing area on said surface of said third chip to connect said third notch or said third aperture to said third conductive area,
wherein a conductive material is obtained in each of said third apertures.

7. The device according to claim 1,
wherein said first apertures and said second apertures together with said first insulative layer and said second insulative layer are obtained in said first chip and said second chip in an oxygen environment by a hot-drilling device, respectively.

8. The device according to claim 1,
wherein said hot-drilling device is a laser device.
